(19) United States
(12) Patent Application Publication
(10) Pub. No.: US 2007/0290375 A1
(43) Pub. Date: Dec. 20, 2007

(54) ACTIVE DEVICE ARRAY MOTHER SUBSTRATE

(76) Inventor: Chin-Hai Huang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/308,966

(22) Filed: Jun. 1, 2006

(51) Int. Cl. H01L 23/48; H01L 23/52; H01L 29/40

(52) U.S. Cl. 257/786

(57) ABSTRACT

An active device array mother substrate suitable for being divided into a plurality of active device array substrates is provided. The active device array mother substrate includes a substrate, multiple sets of active device arrays, and a plurality of outer circuit pads. The substrate has a plurality of predetermined regions defining the positions of the active device array substrates respectively. Furthermore, the multiple sets of active device arrays are disposed in the predetermined regions respectively and the pads are also disposed in the predetermined regions. The pads and the active device arrays in the predetermined regions are electrically connected to each other. Particularly, the pads of at least two predetermined regions are electrically connected to each other.

### BACKGROUND OF THE INVENTION

1. Field of Invention

The present invention relates to an active device array mother substrate. More particularly, the present invention relates to an active device array mother substrate capable of resisting electro static discharge (ESD).

2. Description of Related Art

During the manufacture of a liquid crystal display (LCD), operators, machines, or test instruments may carry static electricity. When objects carrying static electricity (i.e., operators, machines, or test instruments) contact an LCD panel, the devices and circuits inside the LCD panel may be damaged by the ESD. Therefore, an ESD protection circuit is designed in the non-display area of the common LCD panel. For the active matrix LCD panel, the ESD protection circuit is formed on the substrate during the manufacture of the active device array and then electrically connected to the active device array. Thus, when the LCD panel suffers the impact of an ESD, the protection mechanism of the ESD protection circuit is activated to disperse and weaken the static electricity, thereby preventing the static electricity from directly entering and damaging the devices and the circuits in the display area.

FIG. 1 is a schematic view of a conventional active device array substrate. The active device array substrate 100 shown in FIG. 1 comprises an active device array 120, a plurality of external circuit pads 150, and an ESD circuit 160, formed on a substrate 110, wherein the substrate 110 has a display area 112 and a peripheral region 114. The active device array 120 is located within the displaying region 112 and comprises a plurality of active devices 122, a plurality of pixel electrode 124, a plurality of scan lines 130, and a plurality of data lines 140. In particular, the scan lines 130 and the data lines 140 are used for driving the corresponding active devices 122 and the active devices 122 can drive the pixel electrode 124. Further, the active device array 120 is electrically connected to the external circuit pads 150 by the scan lines 130 and the data lines 140, and is electrically connected to an outer drive circuit (not shown) by the external circuit pads 150.

In the current flat display, the usual ESD protection circuit 160 comprises inner ESD protection ring 162 and outer ESD protection ring 164. The inner ESD protection ring 162 is electrically connected between the external circuit pads 150 and the active device array 120. When the ESD phenomenon occurs on the active device array 120, the electro-static charges with high voltage may turn on the inner ESD protection ring 162 and the charges are dispersed by the inner ESD protection ring 162. Furthermore, in order to prevent the ESD damage from occurring between external circuit pads 150 and the outer drive circuit, the outer ESD protection ring 164 is disposed at the periphery of the substrate 110 and electrically connected to the external circuit pads 150. Similarly, when the ESD occurs on anyone of the external circuit pads 150, the electro-static charges with high voltage may turn on the outer ESD protection ring 164 and the charges are dispersed by the outer ESD protection ring 164.

FIG. 2 is drawing, schematically illustrating a conventional substrate of the active device array. Referring to FIG. 2, in general, the process of manufacturing the foregoing active device array substrate 100 includes: defining a plurality of predetermined regions A on a large piece of glass substrate 101; forming a desired active device array 120 and the associated circuits in the predetermined regions A; finally, cutting the large piece of glass substrate 101 into a plurality of active device array substrates. In consideration of economic benefit, the distance between the predetermined regions A is made as small as possible to increase the utilization rate of the glass substrate 101. Therefore, a Chip On Glass (COG) technology has been developed in recent years, in which a drive circuit chip is directly attached to the external circuit pad 150 of the glass substrate 101 and electrically connected to a flexible printed circuit board (not shown), adhered on the pad 160, by the external circuit pads 150, thereby saving space.

However, if the outer ESD protection ring 164 is included in the COG technology, then it then causes the issue of circuit line interference for the circuit line on glass substrate 101. Further, when the distance between predetermined regions A becomes smaller, the area of the glass substrate 101 becomes insufficient to load the outer ESD protection ring 164. In other words, in the conventional COG technology, the active device array 120 on the glass substrate 101 can only use the inner ESD protection ring to disperse the electro-static charges. As such, the ability of resisting the ESD damage for each active device array 120 is reduced significantly, thus resulting in a high risk of ESD damage for the devices and circuits in the active device array 120.

### SUMMARY OF THE INVENTION

An object of the present invention is to provide an active device array mother substrate to prevent the ESD damage from occurring on each active device array of the mother substrate.

In order to achieve the aforementioned and other objects, the present invention provides an active device array mother substrate suitable for being divided into a plurality of active device array substrates. The active device array mother substrate comprises a substrate, multiple sets of active device arrays and a plurality of outer circuit pads. The substrate has a plurality of predetermined regions defining the positions of the active device array substrates respectively. Furthermore, the multiple sets of active device arrays are disposed in the predetermined regions respectively, and each set of active device arrays has multiple signal lines. The outer circuit pads are also disposed in the predetermined regions. The signal lines in each predetermined region are respectively electrically connected to the outer circuit pads. Particularly, the outer circuit pads of at least two predetermined regions are electrically connected to each other.

In one embodiment of the invention, the active device array mother substrate in each predetermined region further includes multiple drive chip pads and an inner ESD protection ring. Wherein, the dive chip pads are electrically connected to the signal lines of the active device array, and the inner ESD protection ring is electrically connected between the dive chip pads and the signal lines. The inner ESD protection ring is further electrically connected to at least one of the outer circuit pads within the predetermined region.

In one embodiment of the invention, each foregoing ESD protection ring includes multiple protection devices and a connecting wire. Wherein, the protection devices are electrically connected between the signal line and the drive chip pads, respectively. Furthermore, the protection devices are connected to each other through the connecting wire.

In one embodiment of the invention, the active device array mother substrate further comprises a lead wire disposed on the substrate and outside the predetermined regions. The outer circuit pads are electrically connected to the lead wire for electrically connecting the active device arrays to each other through the connecting wire.

In one embodiment of the invention, the active device array mother substrate further comprises a plurality of switching devices, respectively electrical connecting between the outer circuit pads and the lead wire. The switching devices are, for example, thin film transistor, diode, or both in combination.

In one embodiment of the invention, the outer circuit pads include a plurality of first pads and a plurality of second pads. The signal line in each predetermined region comprises a plurality of data lines, and a plurality of scan lines. The scan lines are electrically connected to the first pads in the predetermined region, respectively. The first pads and the scan lines are in the same film layer. The data lines are electrically connected to the second pads. The second pads and the data lines are at the same film layer.

In one embodiment of the invention, the lead wire comprises, for example, a first conductive layer and a second conductive layer, and the second conductive layer is over the first conductive layer.

In one embodiment of the invention, the lead wire is, for example, a transparent conducting layer and both the first conductive layer and the second conductive layer are electrically connected to transparent conducting layer.

In one embodiment of the invention, the material of the transparent conducting layer includes indium tin oxide or indium zinc oxide.

In one embodiment of the invention, in each predetermined region, the active device array mother substrate further comprises a plurality of bus wires and the signal lines of the active device array includes multiple common lines. Each of the common lines are electrically connected to the outer circuit pads, respectively, by the bus wires. The bus wires in different predetermined regions are electrically connected to each other by at least one of the outer circuit pads.

On the active device array mother substrate of the invention, the pads of at least two predetermined regions are electrically connected to each other, and thereby the circuits in different predetermined regions are electrically connected to each other. Therefore, when ESD phenomenon occurs on a certain one of the active device arrays, the static charges are further dispersed to the whole mother substrate, so as to reduce the impact on any individual active device array.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a schematic view of a conventional active device array mother substrate.

FIG. 2 is a schematic view of a conventional active device array mother substrate.

FIG. 3 is a schematic view of an active device array mother substrate of the first embodiment of the invention.

FIG. 4 is a schematic view of an active device array mother substrate of the second embodiment of the invention.

FIG. 5A is a schematic view of the active device array mother substrate along the cross-section line I-I′ in FIG. 3, according to an embodiment of the invention.

FIG. 5B is a schematic view of the active device array mother substrate along the cross-section line I-I′ in FIG. 3, according to another embodiment of the invention.

FIG. 6 is a schematic view of an active device array mother substrate of the third embodiment of the invention.

### DESCRIPTION OF EMBODIMENTS

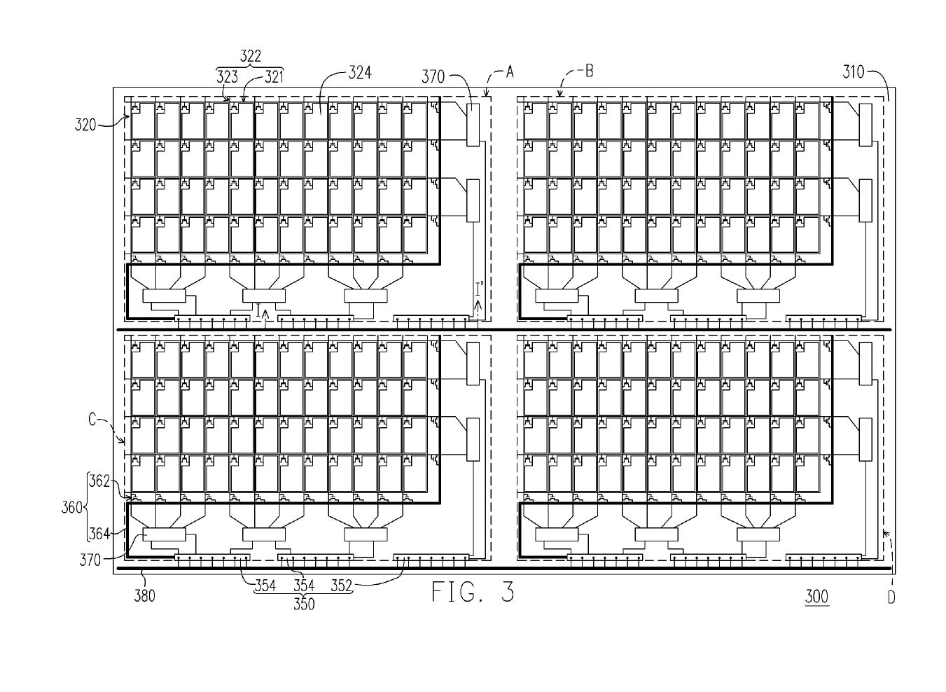

FIG. 3 is a schematic view of an active device array mother substrate of the first embodiment of the invention. With reference to FIG. 3, the active device array mother substrate 300 is suitable for being divided into a plurality of active device array substrates. Specifically, the active device array mother substrate 300 comprises a substrate 310, multiple sets of active device arrays 320, and a plurality of outer circuit pads 350. The substrate 310 has, for example, a plurality of predetermined regions A, B, C, and D. The active device arrays 320 of each set are respectively disposed in the predetermined regions A, B, C, and D. That is, the active device array mother substrate 300 in the embodiment can be divided into four active device array substrates in the later process. Of course, the number of the predetermined regions on the substrate 210 is not limited to the above, and can be adjusted according to the size and quantity of active device array substrates to be manufactured.

Still referring to FIG. 3, each set of the active device array 320 has multiple signal lines 322. As known by one in ordinary skill, the signal lines includes the scan line 321 and the data line 323. Furthermore, multiple outer circuit pads 350 are disposed in each of the predetermined regions A, B, C, and D. The outer circuit pads 350 in each of the predetermined regions A, B, C, and D are electrically connected to the corresponding active device arrays 320. It can be known clearly from FIG. 3 that the active device array 320 is connected to the outer circuit pads 350 through the scan lines 321 or the data lines 324. Here, the outer circuit pads are, for example, used to electrically connected to the flexible printed circuit (FPC) (not shown).

It should be especially noted that the outer circuit pads 350 in at least two predetermined regions on the active device array mother substrate 300 are electrically connected to each other. In this manner, when the ESD phenomenon occurs on the active device array 320 in anyone predetermined region, the electro-static charges are conductively dispersed to the whole substrate 310 and it can further prevent the ESD damage from occurring on any electronic device of the substrate 310.

Specifically, in each of the predetermined regions A, B, C, and D, the active device array mother substrate 200 further comprises a plurality of inner ESD protection ring 360 a plurality of drive chip pads 370s. The drive chip pads 370 are electrically connected between the signal lines 322 and the outer circuit pads 350. In other words, the signal lines 322 of the active device array 320 are firstly electrically connected to the dive chip pads 370 and then electrically connected to the outer circuit pads 350 by the dive chip pads 370 wherein, the dive chip (not shown), which is to be adhered to the substrate 310 later, can be adhered to dive chip pads 370.

In each predetermined region, the inner ESD protection ring 360 is electrically connected between the signal lines 322 and the drive chip pads 370. Furthermore, inner ESD protection ring 360 is, for example, composed from multiple protection devices 362 and a connecting wire 364. The protection devices 362 are, for example, thin film transistor, diode, or both in combination. The connecting wire 364 is used to connect the protection devices 362 in series, and the connecting wire 364 is further electrically connected to at least one of the outer circuit pads 350. In this manner, when the ESD phenomenon occurs on the active device array 320, the electro-static charges are moving to inner ESD protection ring 360 through the signal lines 322 and turn on the protection device 362. As a result, the electro-static charges are further dispersed to outer circuit pads 350 through the connecting wire 364. At this situation, sine the outer circuit pads 350 of different predetermined regions of the active device array mother substrate 300 in the invention are electrically connected to each other, the electro-static charges are further dispersed to the other predetermined regions by the outer circuit pads 350. It can prevent the electro-static charges form over concentrating, resulting in damage on the active device array 320.

In the embodiment, the active device array mother substrate 300 uses, for example, a lead wire 380 to electrically connect the outer circuit pads 350 of different predetermined regions, and to further connect the active device arrays 320 in different predetermined region A, B, C, and D, by the lead wire 380. Wherein, the lead wire 380 is disposed on the substrate 310 and located at outside of the predetermined region. It should be noted that the lead wire 380 can be formed with the together with the outer circuit pads 350, the scan lines 321, or the data lines 323. Of course, the lead wire 380 can also be a metal wire left over from other processes on the active device array mother substrate 300. In other words, the lead wire 380 can be formed without adding any process in the invention.

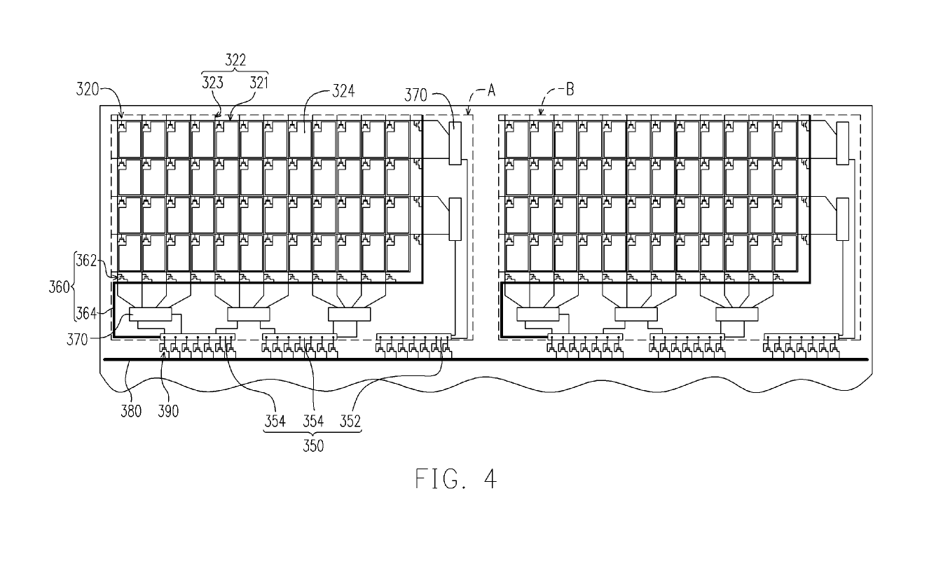

In addition, the invention can further implement the switching devices 390 between the outer circuit pads 350 and lead wire 380. As shown in FIG. 4, the switching device 390 can be, for example, thin film transistor, diode, or both in combination.

Still referring to FIG. 3, when ESD phenomenon occurs on the active device array mother substrate 300, the protection mechanism of the inner ESD protection ring 360 is activated by the high voltage of the static charges, and then the static charges are dispersed and passed to the outer circuit pads 350 through the connecting wire 364. The static charges are further dispersed to the other predetermined regions of the substrate 310 by the lead wire 380. In other words, the static electricity is consumed partly after the protection devices 364 are activated by the static electricity, and static charges are further dispersed fully to the whole substrate 310 through the lead wire 380. Therefore, the damaging capability of ESD is reduced.

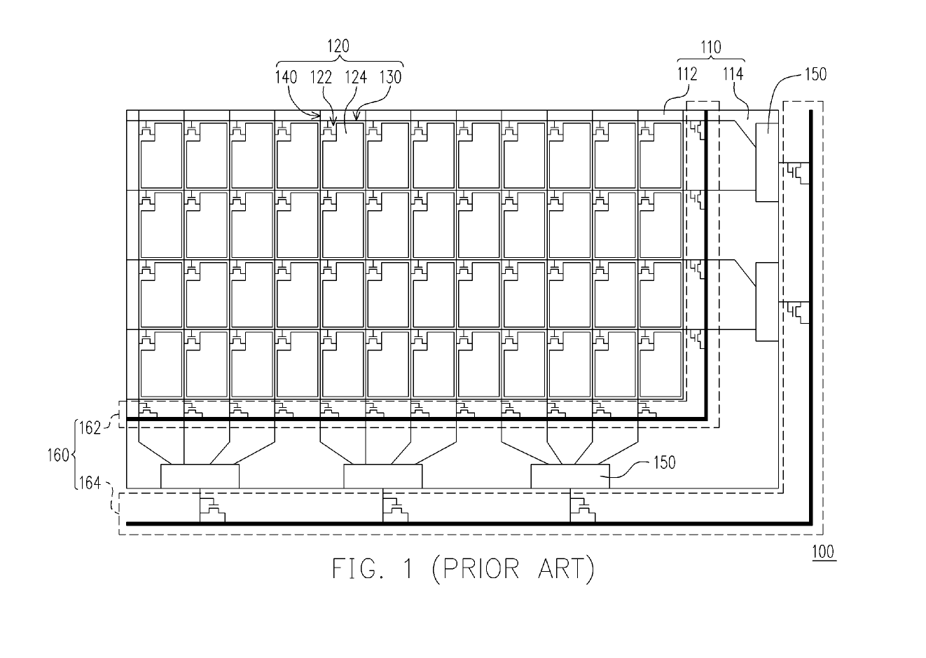

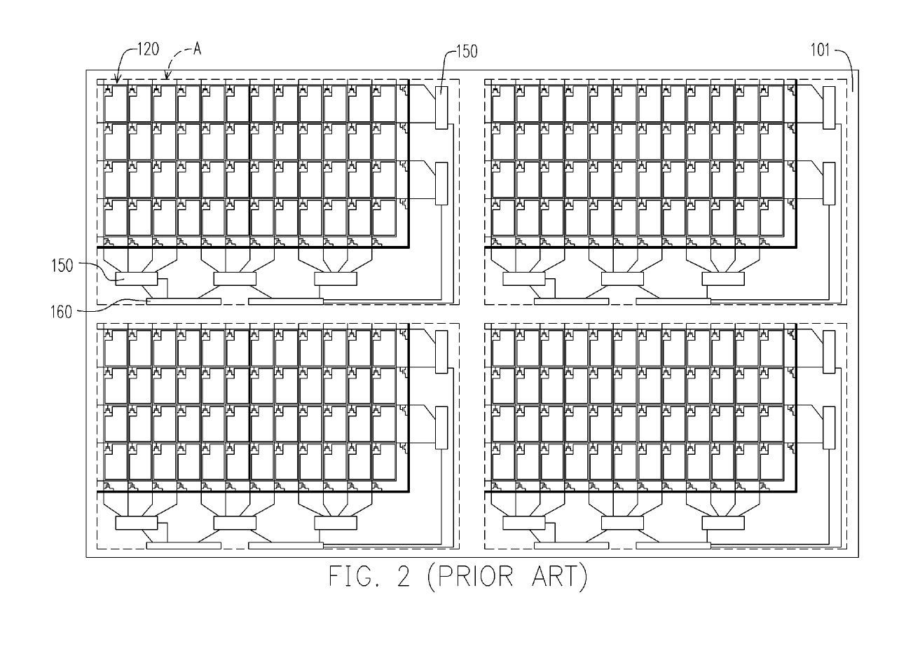

Generally, the foregoing effect is more significant in an active device array mother substrate 300 of larger size, because a larger active device array mother substrate 300 has a longer and wider path to disperse the static electricity, and the energy of the static electricity will be consumed during the transmission process and is dispersed over a larger area, thereby significantly reducing the damage capability of ESD. Therefore, the present invention allows the active device mother substrate 300, which is not suitable for forming the conventional outer ESD protection ring 164 (see FIG. 1), to still have good ESD protection effect. In the practical arrangement, since the active device mother substrate 300 of the embodiment has the no the conventional outer ESD protection ring 164 in FIG. 1, there is no need to perform the additional cutting process to separate the outer ESD protection ring, and then there no need to worry about the limitation due to polishing chamfer angle.

In other hand, since the active device array mother substrate 300 of the embodiment is not using the outer ESD protecting ring for providing the dispersing route of the charges, it can prevent the issue of circuit interference between the outer ESD protection ring and the substrate 310.

In the embodiment, the outer circuit pads 350 includes multiple first pads 352 and multiple second pad 354. The first pads 352 can be, for example, used to hold the flexible printed circuit board (not shown), which is to be electrically connected with the scan line 321. The second pads 354 can be, for example, used to hold the flexible printed circuit board (not shown), which is to be electrically connected with the data line 323. In other words, the san line 321 is electrically connected to the first pads 352, the data line 323 is electrically connected to the second pads 354. Further, the scan line 321 can be the same layer as the first pad 352. The data line 232 can be, for example, the same layer as the second pads 354.

As foregoing description, the one in ordinary skill can know that the scan line 321 and the data line 323 are at the different layers. In other words, the first pads 352 and the second pads 354 are belonging to different film layer. The following descriptions in examples are about how to connect the first pads 353 and the second pads 354 to be electrically connected to the lead wire 380.

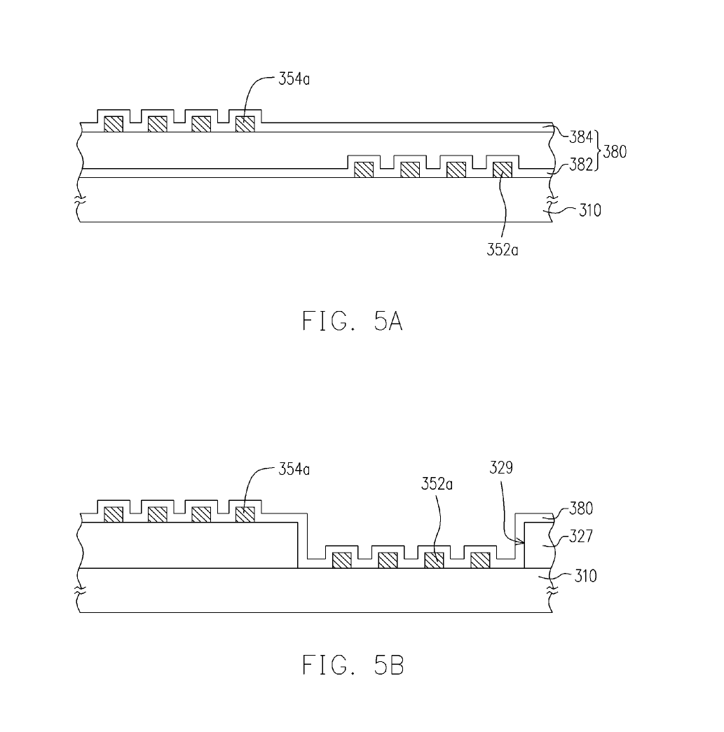

FIG. 5A is a schematic view of the active device array mother substrate along the cross-section line I-I′ in FIG. 3, according to an embodiment of the invention. Referring to FIG. 5A, in the embodiment, the lead wire 380 is formed from the first conductive layer 382 and a second conductive layer 384. The second conductive layer 384 is located over the first conductive layer 382. The first pads 352 are electrically connected to the first conductive layer 382 by the conductive line 352a. The second pads 354 are electrically connected to the second conductive layer 384 by the conductive line 354a.

FIG. 5B is a schematic view of the active device array mother substrate along the cross-section line I-I′ in FIG. 3, according to another embodiment of the invention. Referring to FIG. 5B, in the embodiment, the lead wire 380 is a single film layer and is electrically connected to the first pad 352 and the second pads 354 in different layers. Specifically, the lead wire 380 is, for example, located over the film layer of the first pad 352 and the second pads 354. It can be, for example, directly covering the conductive line 354a, extending out from the second pads 354. A contact opening 329 in the dielectric layer 327 between the first pads 352 and the second pad 354 is used for allowing the lead wire 380 to electrically connect to the conductive line 352a, extending out from the first pads 352. For example, the lead wire 380 is, for example, a transparent conductive layer and can be, for example, formed in the same masking process for forming the pixel electrode 324 of the active device array 320 (see FIG. 3). In other words, the material for the lead wire 380 can be indium tine oxide (ITO) or indium zinc oxide.

Referring to FIG. 3 and FIG. 5B, if the ESD phenomenon occurs on the scan line 321 of the active device array 320, the static charges can flow to the lead wire 380 by the first pads 352, and are dispersed to the second pads 354 by the lead wire 380. Further the data line 323 and the scan line 321 are at the same voltage level. Likewise, if the ESD phenomenon occurs on the data line 323 of the active device array 320, the static charges can flow to the lead wire 380 by the second pads 354, and are dispersed to the first pads 352 by the lead wire 380. Further the data line 323 and the scan line 321 are at the same voltage level. As a result, it can effectively reduce the impact of ESD on the active device array mother substrate 300, and achieve the protection of the active device array mother substrate 300.

Remarkably, when each set of the active device arrays 320 on the substrate 310 is too close without having sufficient space to dispose the lead wire 380 of FG. 3, the invention can still have other method to electrically connect the outer circuit pads 350s in different predetermined regions. The example is as follows.

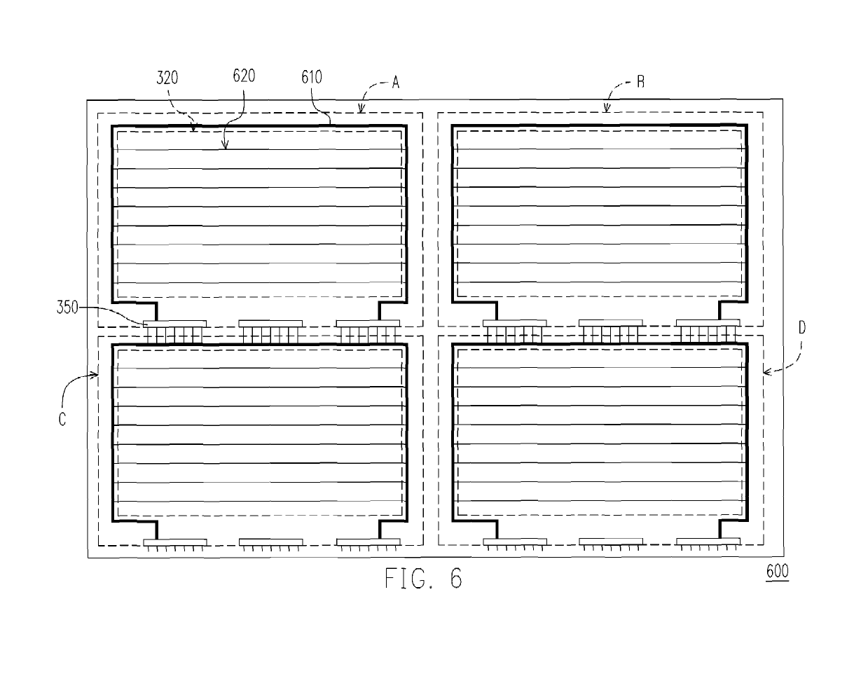

FIG. 6 is a schematic view of an active device array mother substrate of the third embodiment of the invention. To emphasize the characteristics of the invention, some devices are not shown in FIG. 6; instead, only the connection method among the circuits in different predetermined regions is illustrated. With reference to FIG. 6, each predetermined region in the active device array mother substrate 600 further includes a bus wire 610, and the signal lines of each set of the active device arrays 320 include the scan lines 321 and the data lines 323 in FIG. 3 and further includes multiple common lines 620. The bus wires 610 in each predetermined region are electrically connected to the common lines 620 for transmitting the signals provided from outside to common lines 620. It can be known clearly from FIG. 6 that the bus wire 610 is surrounding the periphery of the active device array 320 and electrically connected to the outer circuit pads 350. Particularly, the outer circuit pads 350 of the invention are electrically connected between the bus wires 620 of two predetermined regions. When ESD phenomenon occurs on the active device array mother substrate 600 at the active device array 320 in a certain predetermined region, the electro-static charges flow to the outer circuit pads 350 from the common lines 620 and through the bus wire 610. Further, the electro-static charges are further dispersed to the other predetermined region by the outer circuit pads 350. As a result, the impact of the ESD on the active device array mother substrate 600 can be reduced effectively, achieving the purpose of protecting the active device array mother substrate 600.

It should be noted that even though the bus wires 610 in the predetermined regions A and C, in FIG. 6, are electrically connected to each other via the outer circuit pads 350, those skilled in the art should know that in practice, the bus wires 6100 in other predetermined region B or D can be further connected together, which is not particularly limited herein.

In view of the above, the active device array mother substrate of the invention has at least the following advantages.

1. In the invention, the active device arrays in different predetermined regions on the active device array mother substrate are electrically connected to significantly increase the paths and area for dispersing static electricity. As such, when ESD happens, the static electricity is dispersed fully, thus significantly reducing the damage potential of ESD, and achieving the purpose of protecting each active device array. Furthermore, the outer circuit pads can be protected from being damaged by ESD during the process of adhering the flexible printed circuit boards.

2. The active device array mother substrate of the invention is capable of resisting ESD effectively without outer ESD protection short-rings. Therefore, the invention is suitable for use the COG technology in the manufacturing process for forming the active device array substrate.

3. The lead wire on the active device array mother substrate of the invention is formed in the original fabrication process, and the active device array mother substrate is capable of resisting ESD damage without outer ESD protection short-rings thereon. Therefore, the manufacturing cost of the active device array mother substrate of the invention is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active device array mother substrate, suitable for being divided into a plurality of active device array substrates, comprising:
a substrate having a plurality of predetermined regions defining the positions of the active device array substrates, respectively;
a plurality of sets of active device arrays disposed in the predetermined regions respectively, wherein each of the active device arrays includes a plurality of signal lines; and
a plurality of outer circuit pads disposed in the predetermined regions, and the signal lines are electrically connected to the external circuit pads in each predetermined region,
wherein the outer circuit pads of at least two of the predetermined regions are electrically connected to each other.

2. The active device array mother substrate as claimed in claim 1, in each predetermined region further comprising:
a plurality of drive chip pads, electrically connected to the signal lines of the active device array, respectively; and
an ESD protection ring, electrically connected between the drive chip pads and the signal lines, and the inner ESD protection ring electrically connecting to one of the outer circuit pads.

3. The active device array mother substrate as claimed in claim 2, wherein the inner ESD protection ring comprises:
a plurality of protection devices, electrically connected between the signal lines and the drive chip pads, respectively; and
a connecting wire, connecting the protection devices in series, and electrically connecting to the one of the outer circuit pads.

4. The active device array mother substrate as claimed in claim 2, further comprising a lead wire disposed outside the predetermined regions on the substrate, wherein the outer circuit pads in each predetermined region are electrically connected to the lead wire, so that the active device arrays are electrically connected with each other through the lead wire.

5. The active device array mother substrate as claimed in claim 4, further comprises a plurality of switching devices, electrically connecting between the outer circuit pads and the lead wire.

6. The active device array mother substrate as claimed in claim 5, wherein the switching devices comprise at least one of thin film transistor and diode.

7. The active device array mother substrate as claimed in claim 4, wherein the outer circuit pads include a plurality of first pads and a plurality of second pads, and the signal lines in each predetermined region further comprises:
a plurality of data lines, electrically connected to the first pads in the predetermined region respectively, the first pads and the data lines formed by a same film layer; and
a plurality of scan lines, electrically connected to the second pads in the predetermined region respectively, the second pads and the scan lines formed by a same film layer.

8. The active device array mother substrate as claimed in claim 7, wherein the lead wire comprises a first conductive layer and a second conductive layer, the second conductive layer is over the first conductive layer, the first pads are electrically connected to the first conductive layer, and the second pads are electrically connected to second conductive layer.

9. The active device array mother substrate as claimed in claim 7, wherein the lead wire is a transparent conducting layer, and the first pads and the second pads are electrically connected to the transparent conducting layer.

10. The active device array mother substrate as claimed in claim 9, wherein the material of the transparent conducting layer includes one of indium tin oxide and indium zinc oxide.

11. The active device array mother substrate as claimed in claim 1, further comprising a bus wire, and in each predetermined region, the signal lines of the active device array comprising:
a plurality of common lines, the common lines being electrically connected to the outer circuit pads through the bus wire, and the bus wires in the different predetermined regions are electrically connected to each other by at least one of the external circuit pads.
